(19) United States
(12) Patent Application Publication
(10) Pub. No.: US 2004/0252738 A1
(43) Pub. Date: Dec. 16, 2004

(54) Light emitting diodes and planar optical lasers using IV semiconductor nanocrystals

(76) Inventor: Steven E. Hill, Castile Rock, CO (US)

Correspondence Address: DOWELL & DOWELL PC, 2111 Eisenhower Ave., Suite 406, Alexandria, VA, 22314, US

(21) Appl. No.: 10/761,408

(22) Filed: Jan. 22, 2004

Related U.S. Application Data
(60) Provisional application No. 60/441,413, filed on Jan. 22, 2003.
(60) Provisional application No. 60/441,485, filed on Jan. 22, 2003.
(60) Provisional application No. 60/450,661, filed on Mar. 3, 2003.

(51) Int. Cl. H01S 5/00

(52) U.S. Cl. 372/43

(57) ABSTRACT

Lasers and LEDs are provided which are implemented with rare earth doped group IV semiconductor nanocrystal material.

### RELATED APPLICATIONS

This application claims the benefit of U.S. Provisional Application Nos. 60/441,413 filed Jan. 22, 2003, 60/441,485 filed Jan. 22, 2003 and 60/450,661 filed Mar. 3, 2003.

### FIELD OF THE INVENTION

The present invention relates to applications of group IV semiconductor nanocrystals, more specifically, light emitting diodes and planar optical lasers.

### BACKGROUND OF THE INVENTION

The dominant semiconductor material is silicon and it has been called the “engine” behind the information revolution. A downside of silicon is that it has poor optical activity due to it's indirect band gap which has all but excluded it from the optoelectronics whose exponential growth rate surpasses even the vaunted “Moore's Law” of silicon integrated circuits. In the past two decades there have been highly motivated attempts at developing a silicon-based light source that would allow one to have digital information processing and optical communications capabilities in a single integrated silicon-based integrated structure. For this to be of any practical use, several important issues need to be addressed than just generating light. The silicon Light Emitting Diode (LED) source should (1) emit at a technologically important wavelength, (2) achieve its functionality under practical conditions (e.g. temperature and pump power), and (3) offer competitive advantage over existing technologies.

One of the materials that has gathered much international attention is erbium (Er) doped silicon (Si). The light emission from Er-doped Si occurs at the technological important 1.5 micron (μm) wavelength. An Er doped Si emitter has the minimum optical absorption of silica-based optical fibers. By exciting the first excited state of the intra-4f shell atomic transition to the ground state of the Er³⁺ (⁴I_{13/2}-⁴I_{15/2}) it emits photons at the 1.5 micron wavelength. Furthermore it has been shown that both theoretical and experimental results suggest that Er in Si is Auger-excited via carriers, generated either electrically or optically, that are trapped at the Er-related defect sites and then recombine, and that this process can be very efficient due to the strong carrier-Er interactions.

If one tries this strong carrier-Er interaction in Er-doped bulk Si one sees a very reduced efficiency of the Er³⁺ luminescence at practical temperature and pump powers down to impractical levels. In recent papers it has been demonstrated that using silicon-rich silicone oxide (SRSO) which consists of Si nanocrystals embedded in a SiO₂ (glass) matrix reduces many of the problems associated with bulk Si and can have efficient room temperature Er³⁺ luminescence. The Si nanocrystals act as classical sensitizer atoms that absorb incident photons and then transfer the energy to the Er³⁺ ions, which then fluoresce at the 1.5 micron wavelength with the following significant differences. First, the absorption cross section of the Si nanocrystals is larger than that of the Er³⁺ ions by more than 3 orders of magnitude. Second, as excitation occurs via Auger-type interaction between carriers in the Si nanocrystals and Er³⁺ ions, incident photons need not be in resonant with one of the narrow absorption bands of the Er³⁺. However, existing approaches to developing such Si nanocrystals have only been successful at producing up to 0.03 percent atomic weight and this is not sufficient for practical applications, for example erbium 100 atomic percent of 5.81×10²² atoms cm⁻³, see Applied Physics Letter Vol 72, Num 9, 2 Mar. 1998 pp1092-1094, J. Sin, M. Kim, S. Seo, and C. Lee.

In the past history of the semiconductor development silicon has been considered unsuitable for the optoelectronic applications. This is from the indirect nature of its energy band gap, bulk silicon is indeed a highly inefficient light emitter. There have been different approaches developed to overcome this problem, quantum confinement in silicon nanostructures and rare earth doping of crystalline silicon have received a great deal of attention. Of particular interest is silicon nanoclusters (NC) embedded in SiO₂ in recent years attracted interest of the scientific community as a promising new material for the construction of visible Si-based Light Emitting Diodes (LED).

The telecommunications industry commonly uses optical fibers to transmit large amounts of data in a short time. One common light source for optical-fiber communications systems is a laser formed using erbium-doped glass. One such system uses erbium-doped glass fibers to form a laser that emits at a wavelength of about 1.536 micrometer and is pumped by an infrared source operating at a wavelength of about 0.98 micrometer. One method usable for forming waveguides in a substrate is described in U.S. Pat. No. 5,080,503 issued Jan. 14, 1992 to Najafi et al., which is hereby incorporated by reference. A phosphate glass useful in lasers is described in U.S. Pat. No. 5,334,559 issued Aug. 2, 1994 to Joseph S. Hayden, which is also hereby incorporated by reference. An integrated optic laser is described in U.S. Pat. No. 5,491,708 issued Feb. 13, 1996 to Malone et al., which is also hereby incorporated by reference.

There is a need in the art for an integrated optical system, including one or more high-powered lasers along with routing and other components that can be inexpensively mass-produced. The system should be highly reproducible, accurate, and stable.

### SUMMARY OF THE INVENTION

According to one broad aspect, the invention provides an LED comprising REDGIVN (rare earth doped group IV nanocrystal) material.

In some embodiments, the LED comprises in sequence: a conductive substrate and/or bottom cladding; the REDGIVN in a REDGIVN film; a conductive and transparent layer on top of the REDGIVN film; a first contact on top of the conductive and transparent layer and a second contact on the substrate; wherein the LED is turned on by applying a voltage across the first contact and the second contact.

In some embodiments, the substrate is selected from a group consisting of: comprises p or n silicon substrate or Transparent metal oxide semiconductors such as Zinc Oxide and III V compound semiconductor substrates, and diamond substrate; the REDGIVN layer is a silicon rich silicon oxide (SRSO) film containing silicon nanocrystals doped with a rare-earth precursor; the conductive and transparent layer comprises a poly-silicon layer.

In some embodiments, the LED further comprises a small aperture etched through the first contact to allow emitted light out.

In some embodiments, the first contact is a serpent contact to allow emitted light out.

In some embodiments, the LED comprises additional rare earth dopants in the REDGIVN layer so as to produce multiple colours.

In some embodiments, the LED comprises rare earth dopants for red, green and blue so as to produce white light.

In some embodiments, the LED comprises a plurality of layers of REDGIVN each separated by a buffer layer, and each containing a respective rare earth dopant.

In some embodiments, said plurality of layers of REDGIVN comprise three layers, one each for red, blue and green light.

In some embodiments, the rare earth ion are selected from a group consisting of: for blue light: Tetrakis(2,2,6,6 tetramethyl-3,5-heptanedionato)cerium(IV) and Ce(TMHD)₄; for a green light: Tris(2,2,6,6-tetramethyl-3,5-heptanedionato)erbium (III) Er⁺³(THMD)₃; for a red light: Tris(2,2,6,6-tetramethyl-3,5-heptanedionato)europium (III) and Eu(TMHD)₃.

In some embodiments, the conductive substrate and/or bottom cladding are also transparent so as to allow some light to exit out the bottom of the device.

In some embodiments, there is provided an array of LEDs.

In some embodiments, different rare earth dopants are used in respective subsets of the array.

In some embodiments, an array of LEDs is arranged in groups of three, each group of three including a red light LED, a green light LED and a blue light LED so as to produce an overall white light LED.

In some embodiments, each LED is individually actuatable.

In some embodiments, each of the three LEDS has a respective different rare earth dopant so as to produce one of red, green and blue light.

In some embodiments, each of the three LEDs is individually actuatable.

In some embodiments, the group of LEDs is collectively actuatable.

According to one broad aspect, the invention provides an optical laser comprising REDGIVN material.

In some embodiments, An optical laser comprises: at least one waveguide comprising a REDGIVN channel; at least one feedback element(s) defining a laser- laser-resonator cavity in the waveguide so that laser light is output from the waveguide when pumped; a pump source.

In some embodiments, the pump source is a broadband optical pump source.

In some embodiments, the pump source is an electrical pump source.

In some embodiments, an optical laser comprises a substrate and/or bottom cladding below the waveguide and a top cladding.

In some embodiments, the laser cavity has a size, which is tuned to an excitation wavelength of the rare earth dopant.

In some embodiments, the at least one feedback element(s) comprise a first highly reflective mirror, and a second output coupler mirror which is partially reflective.

In some embodiments, the at least one feedback element(s) comprise a first Bragg grating which is highly reflective, and a second Bragg grating which is which is partially reflective.

In some embodiments, the feedback elements are frequency selective, and are tuned to be most reflective near a resonant frequency of the cavity.

In some embodiments, an optical laser further comprises means for varying the wavelength(s) reflected by the feedback element(s) and varying the effective length of the resonator cavity to thereby tune the laser to a selected wavelength.

In some embodiments, an array of lasers is formed on a common substrate.

In some embodiments, each laser of the array of lasers has resonant characteristics and dopants selected to produce a respective different wavelength.

In some embodiments, each laser has a respective laser cavity having a different length.

In some embodiments, a laser further comprises a Diffraction Bragg reflector (DBR) grating formed into or close to the waveguide is used to tune the wavelength of light supported in the waveguide cavity.

In some embodiments the resonance characteristics of the waveguide cavities are individually selected by varying the pitch of the reflection gratings used to define the cavities which, along with the effective refractive index for the propagated optical mode, determines the wavelengths of light reflected by the gratings.

In some embodiments, a laser comprises a surface-relief grating forming a distributed Bragg reflection grating fabricated on a surface of the wave guide.

In some embodiments, a laser comprises: a conductive substrate having a first electrical contact; a transparent conductive cladding buffer; a layer comprising the wave guide, a second electrical contact on top of the REDGIVN channel; an electrical pump source.

In some embodiments, the at least one feedback element(s) comprise a high reflecting mirror and output coupler at opposite ends of the waveguide to form the resonating cavity.

According to one broad aspect, the invention provides a laser component comprising: a thin film containing REDGIVN and having a plurality of waveguides defined by channels within the substrate; one or more feedback elements for providing optical feedback to the waveguides to form a respective laser-resonator cavity in each wave guide with a distinct resonance characteristic to provide lasing action at a selected wavelength when pumped, wherein injection of pump light at one or more suitable wavelengths into the laser-resonator cavity causes output of laser light at the selected wavelength in accordance with a longitudinal cavity mode of the cavity.

In some embodiments, a laser further comprises: a ferrule having a plurality of spaced-apart attachment sites; and a plurality of optic fibers attached to the ferrule at a respective one of the plurality of spaced-apart attachment sites, each optical fiber also being connected to receive light from a respective one of the resonator cavities.

In some embodiments, the laser-resonator cavities have a plurality of widths on a substrate surface to thereby define a plurality of effective indices of refraction for the cavities, the wavelength of a longitudinal cavity mode being dependent thereon.

### BRIEF DESCRIPTION OF THE DRAWINGS

Preferred embodiments of the invention will now be described with reference to the attached drawings in which:

FIG. 1 is a schematic diagram of a first LED which uses Group IV semiconductor nanocrystals doped with rare-earth ions, provided by an embodiment of the invention;

FIG. 2 is a schematic diagram of another LED provided by an embodiment of the invention, adapted to produce white light;

FIG. 3 is a schematic of an array of LEDs provided by an embodiment of the invention;

FIG. 4 is a schematic diagram of a Fabry-Perot Cavity laser provided by an embodiment of the invention;

FIG. 5 is a schematic diagram of a distributed feedback laser provided by an embodiment of the invention;

FIG. 6 is a schematic diagram of an array of DFB lasers provided by an embodiment of the invention;

FIG. 7 is a schematic diagram of an array of v-grooved lasers; and

FIG. 8 is a schematic diagram of an electrically pumped SRSO laser provide by another embodiment of the invention.

### DETAILED DESCRIPTION OF THE PREFERRED EMBODIMENTS

Applicants provisional application <attorney docket 50422-1> entitled “Preparation of type IV Semiconductor Nanocrystals Doped with Rare-earth Ions and Product Thereof” filed Jan. 22, 2003 teaches methods of preparing group IV semiconductor nanocrystals doped with rare-earth ions. In one embodiment provided in that application, the invention provides a doped type IV semiconductor nanocrystal layer. In another aspect, the invention provides a doped type IV semiconductor nanocrystal powder comprising crystals of a group IV element that bear on their surface atoms of one or more rare earth elements. The powder can also be used to form a layer, for example by including the powder in a layer of a dielectric medium for example spin on glass, or a polymer. That application is incorporated herein in its entirety by reference. Two regular applications <attorney dockets 50422-7; 50422-8> have been filed the same day as this application and are hereby incorporated by reference in their entirety. In the entire description that follows, whenever a rare-earth doped group IV nanocrystal material (REDGIVN material) is referred to, any material taught in the incorporated documents is contemplated.

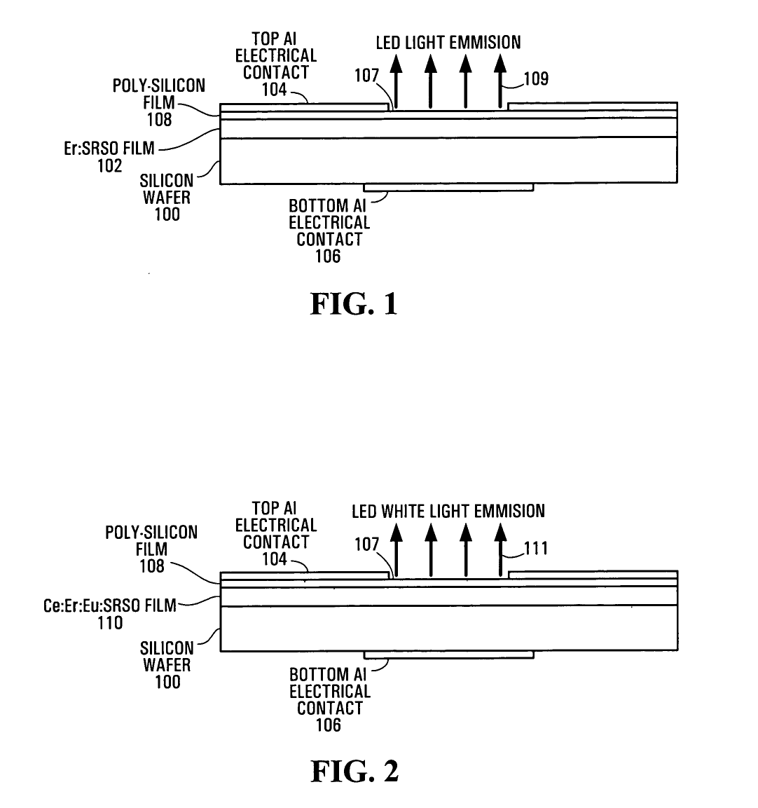

FIG. 1 shows an example structure of an LED that is formed by a Metal Oxide Semiconductor (MOS) structure provided by an embodiment of the invention. This structure uses a p silicon substrate 100 which might for example have a resistivity of 0.001. Any other suitable bottom layer could alternatively be used, for example Zinc Oxide, or Diamond. Preferably the substrate is conductive. On top of the substrate 100 there is a REDGIVN layer 102, for example in the form of an Er:SRSO film. On top of the REDGIVN layer 102 is a conductive, transparent layer 108. This might for example be polysilicon, but other materials may alternatively be used. A bottom first contact 106 is shown below the substrate 100, and a second top contact 104 is shown on top of the conductive transparent layer 108. Also shown is an opening 107 in the top contact layer 104 to allow light to escape.

In operation, the REDGIVN layer 102 is activated by applying a voltage across the two contacts 104,106. The substrate 10 and the transparent conductive layer 108 serve to spread the field created between the two contacts such that substantially all of the REDGIVN layer 102 is activated. The electric field excites the nanocrystals in the REDGIVN layer 102 which in turn excite the rare earth dopants, which then emit at the characteristic wavelengths of the rare earth element.

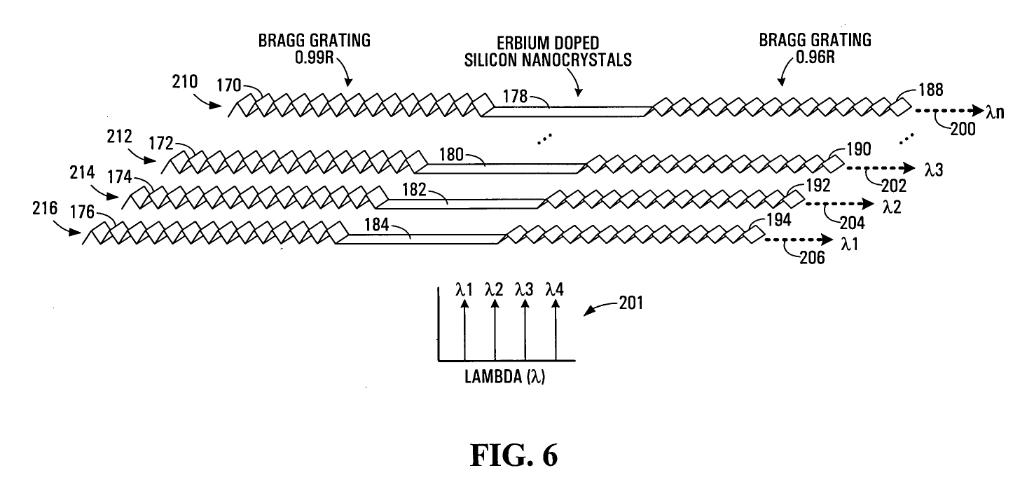

There are several ways of making the device of FIG. 6. The incorporated applications in particular teach a number of ways of forming the REDGIVN layer 102. In an example process of making the device of FIG. 6 that assumes that silicon nanocrystals are employed in the REDGIVN layer 102, the p silicon substrate 100 is cleaned and etched to remove any oxide on the silicon substrate. This cleaned and etched substrate is placed into an ECR PECVD reactor and then exposed to argon plasma for 3 min after pump down to do a final clean off the silicon substrate. During the plasma clean the substrate is brought up to 300° C. silicon substrate, which might for example be n— type with a conductivity of 0.05-0.001 Ωcm, is kept at this temperature during the Silicon Rich Silicon Oxides (SRSO) film growth. A rare-earth precursor is also turned on during the SRSO growth to dope the silicon nanocrystals. The doped SRSO film is grown, preferably from 10 nm to 1000 nm and more preferably from 100 nm-250 nm in thickness. The refractive index of this film can be measured with a ellispometer during the deposition and the silane flow adjusted to have the index of refraction be 1.85 to 1.9. This allows the SRSO film to have a Si content on the order of 42-45 at %. This is to insure high conductivity of the SRSO film and small Si nanocrystals on the order of 1 nm diameter. Other values can be employed. The rare earth precursor and oxygen are turned off and a doped p⁺ poly-silicon layer 108 of 10 nm-50 nm thickness and a conductivity of 0.001 for example is grown on top of the SRSO film. An element may be introduced into semiconductor to establish either p— type (acceptors) or n— type (donors) conductivity; common dopants in silicon: p— type, boron, B; n— type phosphorous, P, arsenic, As, antimony, Sb. This is to make sure of a good transparent current sheet for a top electrode. The grown structure is then placed in a RTA furnace and annealed at 950° C. for 5 minutes to form the nanocrystals and optically activate the rare earth ions into it's 3+ or 2+ valance states. The result is an erbium doped SRSO film 102. After the anneal step a top contact Aluminum film 104 for example of 250 nm-1000 nm thick is deposited on top of the doped p⁺ poly-silicon-Er:SRSO film 102. More generally any of the conductive metals can be employed. Aluminum has a good work function energy level so that an ohmic conductor can be made with the boron doped p⁺ poly-silicon layer. Gold would work but may need to have a chrome layer applied first or else it will peel and flake off the surface. The bottom contact 106 is also deposited on to the silicon substrate of a thickness of 500 nm-2500 nm thickness. An anneal of 450° C. for 5 minutes is performed to form a ohmic contact on the back side of the n⁺ silicon substrate. In one embodiment, the small aperture 107 is etched through the top Aluminum contact 104 to allow emitted light 109 out. In another embodiment, a serpent top front contact can be employed to allow light exit.

An appropriate selection of the rare earth ion can be used to tailor the colour of the emitted light 109 from the prepared LED. For a blue light emitting diode, the rare earth metal precursor can be selected from Tetrakis(2,2,6,6-tetramethyl-3,5-heptanedionato)cerium(IV) and Ce(TMHD)₄. For a green light emitting diode, the rare earth metal precursor can be selected to be Tris(2,2,6,6-tetramethyl-3,5-heptanedionato)erbium (III) Er⁺³(THMD)₃. For a red light emitting diode, the rare earth metal precursor can be selected from Tris(2,2,6,6-tetramethyl-3,5-heptanedionato)europium (III) and Eu(TMHD)₃. This selection of rare earth metal ion precursors is not meant to be limiting.

In another embodiment, in order to extract light also from the bottom of the LED, the layer below the REDGIVN layer 102 is also transparent (but still conductive), and an appropriately shaped bottom contact is employed.

FIG. 1 is an example of a white light LED structure based on the structure of FIG. 1 but with the REDGIVN layer 102 replaced with a REDGIVN layer 110 doped with three different rare earth ions, one for each of blue, red and green light to generate three different types of light which collectively produce a white light emission 111. The layer 110 can be formed by simultaneously doping using different rare earth ions. In a preferred embodiment, a separate layer is used for each dopant. In some embodiments a buffer layer, for example of p⁺ poly silicon, is provided between each rare earth layer. In one example, the active region consists of a layer of REDGIVN doped with a first rare earth ion, a buffer layer of p⁺ polysilicon, a second layer of REDGIVN doped with a second rare earth ion, a buffer layer of p polysilicon, and a third layer of REDGIVN doped with a third rare earth ion, with the three layers containing respective dopants to produce red, green and blue. More generally any combination of dopants may be employed.

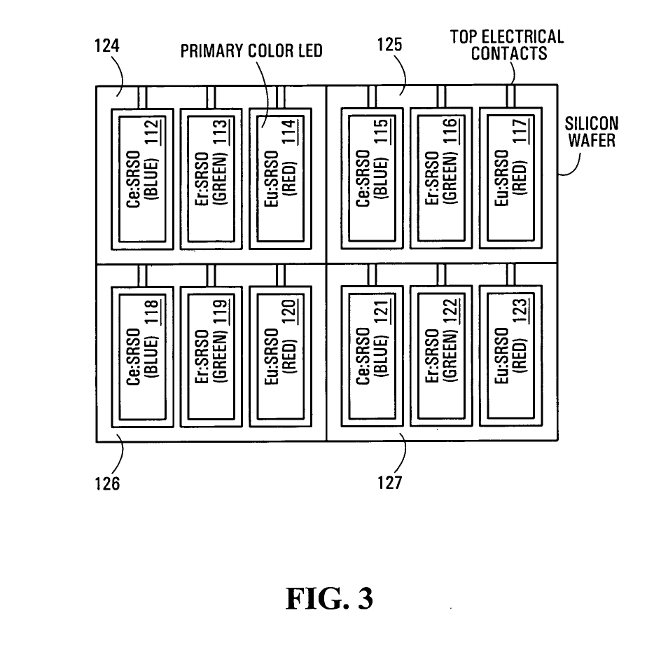

Referring now to FIG. 3, shown is an array of LEDs provided by an embodiment of the invention. In the illustrated example, there are twelve LEDs 112, . . . ,123 each based on the above described embodiment. LEDs 112,115,118,121 are blue LEDs; LEDs 113,116,119,122 are green LEDs, and LEDs 114,117,120,123 are red LEDs, the colour of each LED being determined by the appropriate selection of the rare earth dopant. The LEDs are also shown in four groups 124,125,126,127 of three LEDs, each group containing a respective LED of each of the three primary colours. Each such set of three LEDs can be used to form a white light LED. In one embodiment, each of the colours making up the group of three is individually actuatable so as to produce a desired colour. In another embodiment, all three LEDs in a group turn on together to produce white light at a point a distance from the device where substantial combination of light has taken place. The arrangement of FIG. 3 can be made using a single layered process by applying the three rare earth dopants in three separate stages while masking the remaining areas. While specific examples of different colours are shown in FIG. 3, it is to be understood that an arbitrary array of LEDs is contemplated.

Another embodiment of the invention provides a planar optical laser that is manufactured by using IV semiconductor nanocrystals that are doped with rare-earth ions such as Scandium, Yttrium and the Lanthanides. The purpose of this technology is to allow one to develop an inexpensive method of manufacturing planar optical lasers for use in the telecommunication industry but is not limited to just that field. This technology is also applicable in advanced high speed back-planes and other high speed hybrid optoelectronic circuits.

Preferably the planar optical laser is fabricated on a flat substrate such as fuse silica and or silicon and other such suitable substrate material. The substrate could also be of a flexible nature assuming that the nanocrystal layer did not crack or peel due to the flexible nature of the substrate. By using silicon wafers as the substrate one then gains access to well-established process and fabricating manufacturing facilities throughout the world. Also by developing the flexible substrate technology one would be able to exploit roll-web processes, which would allow one to print the Planar Optical Circuits, as one would do for newspaper, magazines and other such printing technologies.

One embodiment provides optical structures and methods for producing tunable waveguide lasers. In one embodiment, a waveguide is defined within a glass substrate doped with a rare-earth element or elements by PECVD. Feedback elements such as mirrors or reflection gratings in the waveguide further define a laser-resonator cavity so that laser light is output from the waveguide when pumped optically or otherwise. The wavelengths reflected by the reflection gratings can be varied and the effective length of the resonator cavity can be varied to thereby tune the laser to a selected wavelength. For example, having a Bragg reflector as one of the feedback mirrors would allow the cavity to have a preferential high Q for the resonate of the Bragg reflector which then would re-enforce the laser frequency. The Bragg grating could be made to have a varying frequency response by having the grating tuned, for example by thermal or mechanical stressor a combination of these.

Another embodiment provides apparatus and methods for integrating rare-earth doped lasers and optics on glass substrates. The invention includes a laser component formed from a glass substrate with REDGIVN regions defining a plurality of waveguides defined by channels within the substrate. The laser component may constitute a monolithic array of individual waveguides in which the waveguides of the array form laser resonator cavities with differing resonance characteristics. The channels defining the waveguides may for example be created by exposing a surface of the substrate to which a photo resist is spin on and a mask having a plurality of line apertures corresponding to the channels, which are to be formed. Other processes may be employed.

Another embodiment provides a laser component that includes a thin film doped with one or more optically active rare earth (preferably lanthanide) species and type IV nanocrystals and having a plurality of waveguides defined by channels within the film. As used herein, a “channel within the film” is meant to broadly include any channel formed on or in the substrate, whether or not covered by another structure or layer of substrate. Each substrate waveguide (or “channel”) is defined within the substrate as a region of increased index of refraction relative to the substrate. The semiconductor nanocrystal glass film is doped with one or more optically active rare earth species which can be optically pumped (typically a rare-earth element such as Er, Yb, Nd, or Pr and or other lanthanide elements or a combination of such elements such as Er and Yb) to form a laser medium which is capable of lasing at a plurality of frequencies. Again, any of the layered structures of the incorporated embodiments may be used to form a suitable laser medium. Mirrors or distributed Bragg reflection gratings may be located along the length of a waveguide for providing feedback to create a laser-resonator cavity. One or more of the mirrors or reflection gratings is preferably made partially reflective for providing laser output.

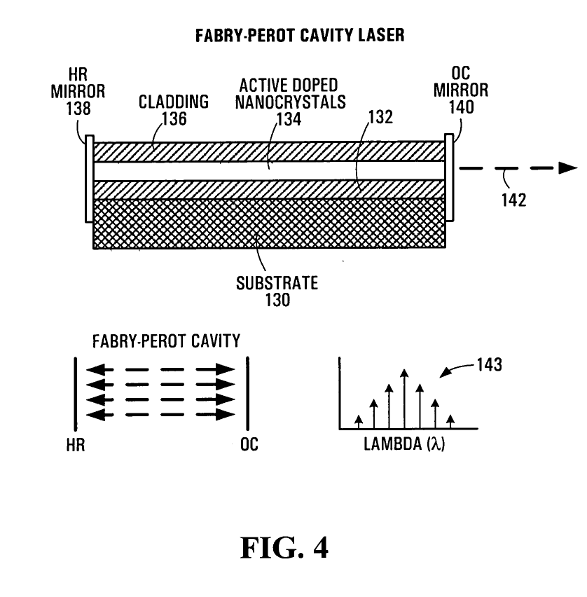

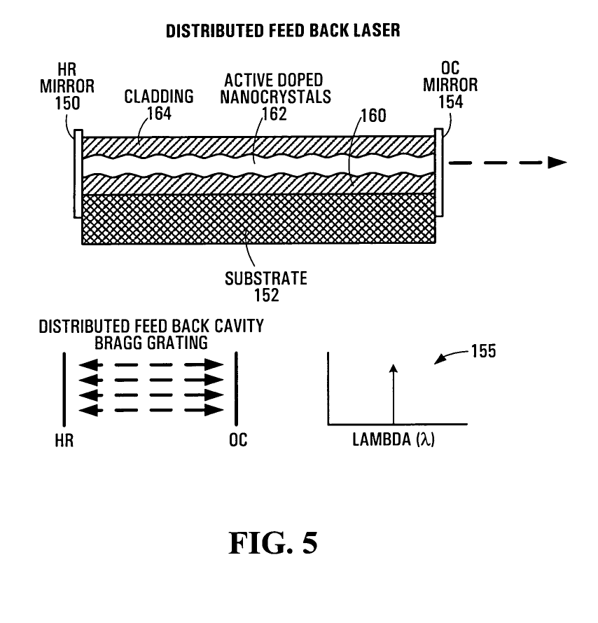

An example of a waveguide laser based Fabry-Perot Cavity laser is shown in FIG. 4. This example shows a substrate 130 which may for example be silica, but could be any other appropriate substrate material. On top of this is a cladding layer 132, a core wave guiding layer 134, and a top cladding layer 136. The wave guiding layer 134 also contains REDGIVN. Also shown is an HR (high reflectivity) mirror 138 and an OC (output coupler) mirror 140. The arrangement of FIG. 4, when pumped, spontaneously emits a light which resonates and eventually exits as output light source 142 through the OC mirror 140 which is partially reflective to allow some light to escape. The laser of FIG. 4 is preferably optically pumped.

In the arrangement of FIG. 4, the feedback components employed are in the form of the pair of mirrors 138,140. This produces a Fabry-Perot Cavity. The laser component may constitute a monolithic array of individual waveguides in which the waveguides of the array form laser resonator cavities with differing resonance characteristics (e.g., resonating at differing wavelengths). The component may thus be used as part of a laser system outputting laser light at a plurality of selected wavelengths.

The frequency response of the arrangement of FIG. 9 is generally indicated at 143 where it has been assumed that Erbium was used as the rare earth dopant. The size of the cavity (distance between HR mirror 138 and OC mirror 140) is tuned to resonate near the active frequencies for Er. This results in the lasing to occur at the active frequencies for Er which include a dominant frequency and several other nearby frequencies which are emitted with less power as shown. In general, the cavity size is preferably substantially matched to the peak in the fluorescence response for the particular rare earth dopant to achieve peak efficiency.

In certain embodiments of the invention, the resonance characteristics of a waveguide cavity are varied by adjusting the width of the channel formed in the film, which thereby changes the effective refractive index of the waveguide. The effective refractive index can also be changed by modifying the diffusion conditions under which the waveguides are formed as described below. A diffraction Bragg reflector (DBR) grating formed into or close to the waveguide is used, in some embodiments, to tune the wavelength of light supported in the waveguide cavity. Changing the effective refractive index thus changes the effective wavelength of light in the waveguide cavity, which determines the wavelengths of the longitudinal modes supported by the cavity. In another embodiment, the resonance characteristics of the waveguide cavities are individually selected by varying the pitch of the DBR reflection gratings used to define the cavities that, along with the effective refractive index for the propagated optical mode, determines the wavelengths of light reflected by the gratings. In still other embodiments, the location of the gratings on the waveguide is varied in order to select a laser-resonator cavity length that supports the desired wavelength of light.

In one embodiment, a surface-relief grating forming a distributed Bragg reflection grating is fabricated on the surface of the waveguide, for example by coating the surface with photo resist, defining the grating pattern in the photo resist holographically or through a phase mask, developing the photo resist pattern, and etching the grating pattern into the waveguide with a reactive ion system such as an argon ion mill. In certain embodiments, a more durable etch mask allowing more precise etching and higher bias voltages is obtained by depositing chromium on the developed photo resist pattern using an evaporation method which causes the chromium to deposit on the tops of the grating lines. This forms a much more durable mask for the reactive ion system allowing a deeper etch which would be required for a thicker active volume.

An example of a distributed feedback laser based on the above embodiment is shown in FIG. 10. This embodiment shows a substrate 152, bottom cladding 160, core 162 and top cladding 164. The reflecting components consist of an HR mirror 150 and an OC mirror 154. In this embodiment, the core is in the form of a distributed bragg reflection grating which might for example have been formed as described above. The shape used to show the core is illustrative of the Bragg grating characteristic that concerns an oscillating index of refraction, and is not necessarily indicative of the physical shape of the core. The core also contains rare-earth doped nanocrystals. The OC mirror 154 in this example is slightly less reflective than the HR mirror resulting in light 166 exiting the arrangement and forming the output of the laser. In this embodiment, the cavity again defines the wavelength of the laser and this needs to be substantially set near the active wavelengths of the rare earth dopants. Preferably, the grating 162 is also tuned to one of these wavelengths. This causes the arrangement to lase substantially at the single frequency for which the arrangement is tuned. Thus, the frequency response of this arrangement, shown generally at 155 has a single peak.

A first example of an array of lasers will now be described with reference to FIG. 6. In this example, there are four lasers generally indicated by 210,212,214,216. Each laser 210,212,214,216 has a respective first Bragg grating 170,172,174,176 (although other reflective elements may alternatively be employed) a respective core area 178,180,182,184 forming a laser cavity and a respective second Bragg grating 188,190,192,194 (although other output reflective elements can be employed. In the illustrated example, one set of gratings 170,172,174,176 is almost completely reflective for example having 99% reflectivity. The other set of gratings 1788,180,182,184 is slightly less reflective to allow some light through as an output signal. In the illustrated example, the second set has 96% reflectivity.

The lasers have outputs 200,202,204,206 which generate wavelengths λn, λ3, λ2, λ1 respectively. It is of course to be understood that any number of lasers can be included in an array such as the array of FIG. 6. Four are shown simply by way of example. Here, the characteristics of each laser in the array are tuned to generate the respective wavelength. This can be done by adjusting the first and second bragg gratings of a given laser and/or by adjusting the length of the cavity. As in previous embodiments, the core region of each laser is constructed using SRSO doped with rare-earth ions. The array of lasers of FIG. 6 can be formed in a single layered structure with the four lasers being side by side in a respective channel within the substrate for example. The frequency response of the arrangement of FIG. 6 is generally indicated at 201, and shows a respective frequency for each laser. In this case, by tuning the bragg gratings a narrow frequency response can be generated for each laser output.

An individual laser can also be formed using the embodiment of FIG. 6. Furthermore, in another embodiment, the arrangement of FIG. 6 is provided, but oriented orthogonally to the arrangement shown. This consists of a substrate, a first layer containing a Bragg grating, a second layer containing the core/cavity, and a third layer containing a second partially reflective Bragg grating. This arrangement produces a laser that emits light out the top of the device.

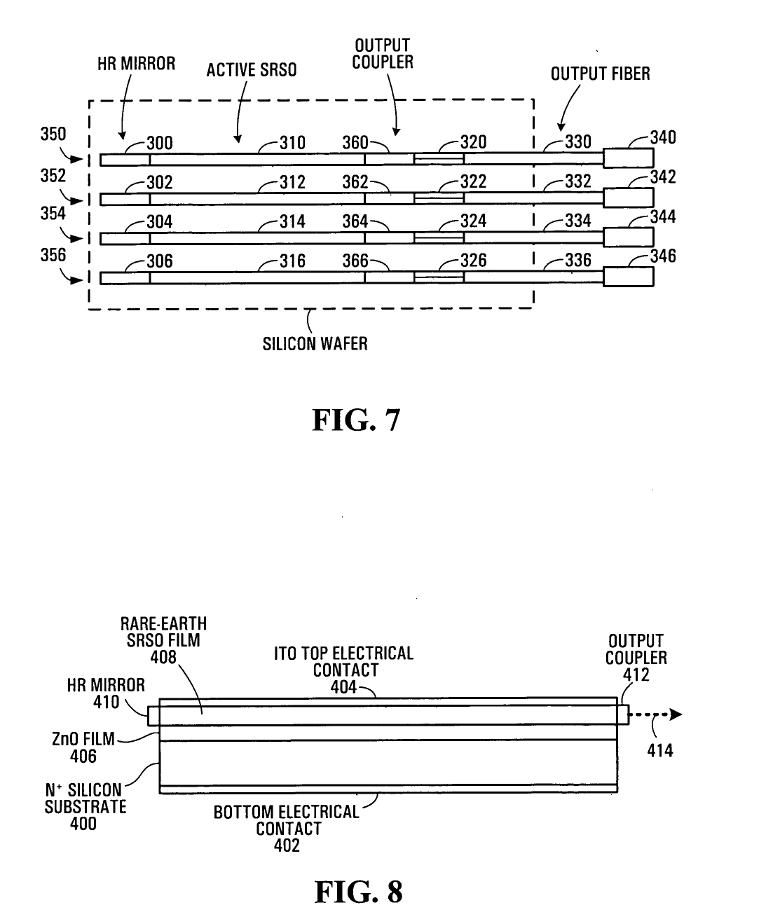

FIG. 7 is another example of an array of lasers provided by an embodiment of the invention. Again, the array is shown to include four separate lasers 350,352,354,356, but any appropriate number of lasers could alternatively be provided. In this embodiment, each laser has an HR mirror 300,302,304,306, and an active SRSO segment 310,312,314,316. The active SRSO segment of each laser is followed by an output coupler 360,362,364,368. The arrangement thus far is substantially similar to the arrangement of FIG. 6, which was a perspective view whereas the view of FIG. 7 is a top view. The output couplers 360,362,364,368 couple the output of the active SRSO segments 310,312,314,316 into a v groove section 320,322,324,326 that in turn is coupled to output fibers 330,332,334,336 connected to output couplers 340,342,344,346.

In a variant of the above described embodiment, the output fibers can be attached to a single a ferrule having a plurality of spaced-apart attachment sites.

The embodiments above have assumed optical pumping. More generally several examples of methods of pumping REDGIVN are provided in applicant's co-pending application no. <attorney docket no. 50422-5> filed on the same day as this application which is based on U.S. provisional application No. 60/441485 hereby, both of which are hereby incorporated by reference in their entirety. Those applications involve pumping for the purpose of amplification. However, the same principles are applicable here for pumping in the context of lasers. Optical pumping and electrical pumping are disclosed and contemplated for these laser applications.

When electrical pumping is used instead of optical pumping the substrate is conductive, for example an n⁺ silicon substrate, to which a transparent conductive cladding buffer such as zinc oxide (ZnO) film, for example of from 2000 to 6000 nm, is applied. A REDGIVN film, for example having a thickness of from 100 to 500 nm, is deposited on transparent conductive layer and annealed. A top electrical contact, for example 500-1000 nm of Indium Tin Oxide (ITO), is deposited on top of the REDGIVN film. Alternatively, a p⁺ poly-silicon layer can also be used as well as a cadmium oxide CdO film and other metal oxides. One would make the choice based on whether the REDGIVN film is a positive (hole) donor or negative (electron) donor. This is then masked and etched to form a active waveguide in which HR mirror and output coupler placed at each end of the waveguide to form the resonating cavity.

FIG. 8 shows an example featuring electrical pumping. Shown is an n+ silicon substrate 400 having a bottom electrical contact 402. Shown is a ZnO film 406 on top of the n+ silicon substrate 400. On top of the ZnO film there is a layer of rare-earth doped SRSO film 408 to which is applied a top contact layer 404 which might for example be Indium Tin Oxide as in the above example. As in some previous embodiments, shown is an HR mirror 410 and an output coupler 412 through which an output light signal 414 passes. More generally, the electrical pumping can be used for any of the embodiments described herein with appropriate modifications.

Numerous modifications and variations of the present invention are possible in light of the above teachings. It is therefore to be understood that within the scope of the appended claims, the invention may be practised otherwise than as specifically described herein.

Y.Kanemitisu, T. Ogawa, K. Shiraishi, and K. Takeda, Phys. Rev. B 48,4883 (1993)

K. S. Min, K. V. Shcheglow, C. M. Yang, H. A. Atwater, M. L. Brongersma, and A. Polman, Appl. Phys. Lett. 69,2033 (1996)

L. Pavesi, L. Dal Negro, C. Mazzolemi, G. Franzo, and F. Priolo, Nature (London)408, 440 (2000)

J. Linnros, N. Lalic, A. Galeckas, and V. Grivickas, J. Appl. Phys. 86, 6128 (1999)

D. Pacifici, A. Irrera, M. Mirtello, F. Iacona, G. Franzo, F. Priolo, D. Sanfilippo, G. Di Stefano, and P. G. Fallica, Appl. Phys. Lett. 81 3242 (2002)

F. Iacona, D. Pacifici, A. Irrera, M. Mirtello, G. Franzo, F. Priolo, D. Sanfilippo, G. Di Stefano, and P. G. Fallica, Appl. Phys. Lett. 81 1866 (2002)

Barbier, D., et al., “Sub-Centimeter length ion-exchanged waveguide lasers in Er/Yb doped phosphate glass”, 11th Ann. Conf. on Integrated Optics and Optical Fibre Comm., vol. 4, pp. 41-44, (1977).

Veasey, D. L., et al., “Distributed Feedback Lasers in Rare-earth-doped phosphate glass”, (Abstract) Proceedings of the 7th European Conference on Integrated Optics with Technical Exhibition, vol. 1, Delft, Nederlands, pp. 579-582, (Apr. 3-6, 1995).

Roman, J. E., et al., “Neodymium-doped glass channel waveguide laser containing an integrated distributed Bragg reflector”, Applied Physics Letters, 61 (23), Amer. Inst. of Physics, pp. 2744-2746, (Dec. 7, 1992). (3 pages)/

We claim:

1. An LED comprising REDGIVN (rare earth doped group IV nanocrystal) material.

2. The LED of claim 1 comprising in sequence:
a conductive substrate and/or bottom cladding;
the REDGIVN in a REDGIVN film;
a conductive and transparent layer on top of the REDGIVN film;
a first contact on top of the conductive and transparent layer and a second contact on the substrate;
wherein the LED is turned on by applying a voltage across the first contact and the second contact.

3. The LED of claim 2 wherein:
the substrate is selected from a group consisting of: comprises p or n silicon substrate or Transparent metal oxide semiconductors such as Zinc Oxide and III V compound semiconductor substrates, and diamond substrate;
the REDGIVN layer is a silicon rich silicon oxide (SRSO) film containing silicon nanocrystals doped with a rare-earth precursor;
the conductive and transparent layer comprises a poly-silicon layer.

4. An LED according to claim 3 further comprising a small aperture is etched through the first contact to allow emitted light out.

5. An LED according to claim 3 wherein the first contact is a serpent contact to allow emitted light out.

6. An LED according to claim 1 comprising additional rare earth dopants in the REDGIVN layer so as to produce multiple colours.

7. An LED according to claim 6 comprising rare earth dopants for red, green and blue so as to produce white light.

8. An LED according to claim 1 comprising a plurality of layers of REDGIVN each separated by a buffer layer, and each containing a respective rare earth dopant.

9. An LED according to claim 8 wherein said plurality of layers of REDGIVN comprise three layers, one each for red, blue and green light.

10. An LED according to claim 9 wherein the rare earth ion are selected from a group consisting of: for blue light: Tetrakis(2,2,6,6 tetramethyl-3,5-heptanedionato)cerium(IV) and Ce(TMHD)₄; for a green light: Tris(2,2,6,6-tetramethyl-3,5-heptanedionato)erbium (III) Er⁺³(THMD)₃; for a red light: Tris(2,2,6,6-tetramethyl-3,5-heptanedionato)europium (III) and Eu(TMHD)₃.

11. An LED according to claim 1 wherein the conductive substrate and/or bottom cladding are also transparent so as to allow some light to exit out the bottom of the device.

12. An array of LEDs each in accordance with claim 1.

13. An array of LEDs according to claim 12 wherein different rare earth dopants are used in respective subsets of the array.

14. An array of LEDs according to claim 12 arranged in groups of three, each group of three including a red light LED, a green light LED and a blue light LED so as to produce an overall white light LED.

15. An array of LEDS according to claim 12 wherein each LED is individually actuatable.

16. A group of three LEDS according to claim 1 wherein each of the three LEDs has a respective different rare earth dopant so as to produce one of red, green and blue light.

17. The group of LEDs according to claim 16 wherein each of the three LEDs is individually actuatable.

18. The group of LEDs according to claim 16 wherein the group of LEDs is collectively actuatable.

19. An optical laser comprising REDGIVN material.

20. An optical laser according to claim 19 comprising:
at least one waveguide comprising a REDGIVN channel;
at least one feedback element(s) defining a laser- laser-resonator cavity in the waveguide so that laser light is output from the waveguide when pumped;
a pump source.

21. An optical laser according to claim 20 wherein the pump source is a broadband optical pump source.

22. An optical laser according to claim 20 wherein the pump source is an electrical pump source.

23. An optical laser according to claim 20 comprising a substrate and/or bottom cladding below the waveguide and a top cladding.

24. An optical laser according to claim 20 wherein the laser cavity has a size, which is tuned to an excitation wavelength of the rare earth dopant.

25. An optical laser according to claim 20 wherein the at least one feedback element(s) comprise a first highly reflective mirror, and a second output coupler mirror which is partially reflective.

26. An optical laser according to claim 20 wherein the at least one feedback element(s) comprise a first Bragg grating which is highly reflective, and a second Bragg grating which is which is partially reflective.

27. An optical laser according to claim 20 wherein the feedback elements are frequency selective, and are tuned to be most reflective near a resonant frequency of the cavity.

28. An optical laser according to claim 20 further comprising means for varying the wavelength(s) reflected by the feedback element(s) and varying the effective length of the resonator cavity to thereby tune the laser to a selected wavelength.

29. An array of lasers according to claim 20 formed on a common substrate.

30. The array of lasers according to claim 29 wherein each laser of the array of lasers has resonant characteristics and dopants selected to produce a respective different wavelength.

31. The array of lasers according to claim 30 wherein each laser has a respective laser cavity having a different length.

32. A laser according to claim 20 further comprising a Diffraction Bragg reflector (DBR) grating formed into or close to the waveguide is used to tune the wavelength of light supported in the waveguide cavity.

33. A laser according to claim 20 wherein the resonance characteristics of the waveguide cavities are individually selected by varying the pitch of the reflection gratings used to define the cavities which, along with the effective refractive index for the propagated optical mode, determines the wavelengths of light reflected by the gratings.

34. A laser according to claim 20 comprising a surface-relief grating forming a distributed Bragg reflection grating fabricated on a surface of the wave guide.

35. A laser according to claim 20 comprising:
a conductive substrate having a first electrical contact;
a transparent conductive cladding buffer;
a layer comprising the wave guide,
a second electrical contact on top of the REDGIVN channel;
an electrical pump source.

36. An optical laser according to claim 35 wherein the at least one feedback element(s) comprise a high reflecting mirror and output coupler at opposite each end of the waveguide to form the resonating cavity.

37. A laser component comprising:
a thin film containing REDGIVN and having a plurality of waveguides defined by channels within the substrate;
one or more feedback elements for providing optical feedback to the waveguides to form a respective laser-resonator cavity in each wave guide with a distinct resonance characteristic to provide lasing action at a selected wavelength when pumped, wherein injection of pump light at one or more suitable wavelengths into the laser-resonator cavity causes output of laser light at the selected wavelength in accordance with a longitudinal cavity mode of the cavity.

38. A laser according to claim 37 further comprising:
a ferrule having a plurality of spaced-apart attachment sites; and
a plurality of optic fibers attached to the ferrule at a respective one of the plurality of spaced-apart attachment sites, each optical fiber also being connected to receive light from a respective one of the resonator cavities.

39. A laser according to claim 37 wherein the laser-resonator cavities have a plurality of widths on a substrate surface to thereby define a plurality of effective indices of refraction for the cavities, the wavelength of a longitudinal cavity mode being dependent thereon.
